(19) United States
(12) Patent Application Publication
(10) Pub. No.: US 2014/0054581 A1
(43) Pub. Date: Feb. 27, 2014

(54) ARRAY SUBSTRATE, MANUFACTURING METHOD THEREOF, AND DISPLAY DEVICE

(71) Applicants: Youngsuk Song, Beijing (CN); Guanbao Hui, Beijing (CN); Seongyeol Yoo, Beijing (CN); Seungjin Choi, Beijing (CN); Feng Zhang, Beijing (CN)

(72) Inventors: Youngsuk Song, Beijing (CN); Guanbao Hui, Beijing (CN); Seongyeol Yoo, Beijing (CN); Seungjin Choi, Beijing (CN); Feng Zhang, Beijing (CN)

(73) Assignee: BOE TECHNOLOGY GROUP CO., LTD., Beijing (CN)

(21) Appl. No.: 13/878,475

(22) PCT Filed: Dec. 23, 2012
(86) PCT No.: PCT/CN2012/087234

§ 371 Date: Apr. 9, 2013

(30) Foreign Application Priority Data
Feb. 28, 2012 (CN) 201210048847.8

(51) Int. Cl. H01L 27/12

(52) U.S. Cl. CPC H01L 27/124; H01L 27/1259
USPC 257/43; 257/59; 257/71; 438/104; 438/155

(57) ABSTRACT

Embodiments of the invention relate to an array substrate, a manufacturing method thereof and a display device comprising the array substrate. The array substrate comprises a gate line and a data line which define a pixel region, the pixel region comprises a thin film transistor region and an electrode pattern region, a gate electrode, a gate insulation layer, an active layer, a source electrode, a drain electrode and a passivation layer are formed in the thin film transistor region, the gate insulation layer, a pixel electrode, the passivation layer and a common electrode are formed in the electrode pattern region, and the common electrode and the pixel electrode form a multi-dimensional electric field. A color resin layer is formed between the gate insulation layer and the pixel electrode.

### BACKGROUND

Embodiments of the invention relate to an array substrate, a manufacturing method of the array substrate and a display device.

Thin film transistor liquid crystal display (TFT-LCD) has advantages of small volume, low power consumption, free of radiation and the like, and occupies a dominant role in current panel display market. With the progress of technology, the consumers have a higher demand on the display effect of mobile products, and the display effect of a normal twisted nematic (TN) type liquid crystal display can not meet such demand any more. At present, many manufacturers have applied various wide viewing angle mode, which have a better display effect, to mobile products, such as in-plane switching (IPS) mode, vertical alignment (VA) mode, advanced-super dimensional switching (AD-SDS, ADS for short) mode and the like. In the ADS mode, a multi-dimensional electric field is formed with both an electric field generated at edges of slit electrodes in a same plane and an electric field generated between a slit electrode layer and a plate-like electrode layer, so that liquid crystal molecules at all orientations, which are located directly above the electrodes or between the slit electrodes in a liquid crystal cell, can be rotated, In this way, the work efficiency of liquid crystal can be enhanced and the light transmittance can be increased. The ADS mode can improve the image quality of the thin film transistor liquid crystal display and has advantages of high transmittance, wide viewing angle, high aperture ratio, low chromatic aberration, high response speed, free of push Mura, etc.

In recent years, the application of liquid crystal display device to mobile phone, personal digital assistant (PDA), flat panel computer and the like gradually increases, and the liquid crystal display device is more and more applied to the outdoor mobile products. However, the normal liquid crystal display device has a poor contrast when being used outdoors under the sunlight so that the readability of the screen is not good. In contrast, the liquid crystal display device with trans-reflective structure can increase the contrast of the display device used outdoors by increasing the reflectivity of the panel, so that the display device with trans-reflective structure can maintain an excellent readability even when being used outdoors. Thus, the wide viewing angle trans-reflective TFT-LCD, which has an excellent display effect and can maintain an excellent readability outdoors, is a development trend of mobile products.

FIG. 1 shows a structure of a conventional TFT array substrate in an ADS mode. The array substrate comprises a gate line and a data line which define a pixel region, and the pixel region comprises a thin film transistor region and an electrode pattern region. A gate electrode 2, a gate insulation layer 3, an active layer 4, a source electrode 5, a drain electrode 6 and a passivation layer 9 are formed in the thin film transistor region. The gate insulation layer 3, a pixel electrode 7, the passivation layer 9 and a common electrode 8 are formed in the electrode pattern region. The common electrode 8 and the pixel electrode 7 form a multi-dimension electric field. This array substrate is applied to the liquid crystal display device, and the liquid crystal display device further comprises a color filter substrate and a back light source in addition to the array substrate. Generally, the array substrate and the color filter substrate are manufactured separately, then the array substrate and the color filter substrate are bonded together by a cell assembly process to form a display panel, and finally the display device is formed by a module process.

However, since the TFT region having a different thickness (as shown in FIG. 1, the passivation layer 9 has an obvious protrusion at the TFT) influences the filling uniformity of the liquid crystal molecules after the cell assembly process, there exists an irregular arrangement of the liquid crystal molecules in the reflective region. In addition, since the pixel electrode is relatively close to the data line, it may be influenced by the voltage of the data line, which is disadvantageous to horizontal driving of the ADS mode. In this case, light leakage may occur because the abnormal liquid crystal driving may cause the rotation angle of the liquid crystal molecules not sufficient. The light from the back light source may not be fully utilized in the display region due to the light leakage, thus the contrast may be reduced, and the display quality may be decreased.

### SUMMARY

According to an embodiment of the invention, there is provided an array substrate. The array substrate comprises a gate line and a data line which define a pixel region, the pixel region comprises a thin film transistor region and an electrode pattern region, a gate electrode, a gate insulation layer, an active layer, a source electrode, a drain electrode and a passivation layer are formed in the thin film transistor region, the gate insulation layer, a pixel electrode, the passivation layer and a common electrode are formed in the electrode pattern region, and the common electrode and the pixel electrode form a multi-dimensional electric field. A color resin layer is formed between the gate insulation layer and the pixel electrode.

According to another embodiment of the invention, there is provided a method of manufacturing an array substrate. The method comprises processes of forming a pixel region, the pixel region comprises a thin film transistor region and an electrode pattern region, a gate electrode, a gate insulation layer, an active layer, a source electrode, a drain electrode and a passivation layer are formed in the thin film transistor region, the gate insulation layer, a pixel electrode, the passivation layer and a common electrode are formed in the electrode pattern region, and the common electrode and the pixel electrode form a multi-dimensional electric field. After forming the gate insulation layer and before forming the pixel electrode, a color resin layer is formed above the gate insulation layer.

According to another embodiment of the invention, there is provided a display device. The display device comprises the above-described array substrate.

According to the embodiments of the invention, since the color resin layer is formed above the gate insulation layer, the distance between the pixel electrode and the data line or the gate line is increased (that is, the interlayer thickness is increased), and thus it is advantageous to make the pixel region to be more flat and prevent the pixel electrode from being influenced by the voltages of the data line and the gate line. Accordingly, the irregular arrangement of the liquid crystal molecules in the reflective region can be prevented, the ADS mode of horizontal driving can be maintained, the proper rotation of the liquid crystal molecules can be ensured, the light leakage can be avoided and the contrast can be improved.

According to the embodiments of the invention, the reflective region pattern is formed by using the metal material for the gate electrode, and the reflective region metal electrode layer is formed by using the metal material for the source and drain electrodes, and the color resin layer is formed on the reflective region metal electrode layer. It is also advantageous to increase the distance between the pixel electrode and the reflective region electrode layer, thus the light leakage caused by the irregular arrangement of the liquid crystal molecules in the reflective region can be prevented. In addition, the disposition of the reflective region (i.e. employing a trans-reflective manner) makes the liquid crystal display device to be able to enhance display effect under a strong light by using extern light, and thus the product quality can be improved and manufacturing cost can be reduced.

According to the embodiments of the invention, since it does not need to bond the array substrate with a separate color filter substrate, the liquid crystal molecules simply is filled between the array substrate and a glass substrate, and thus the alignment difficulty can be reduced. Meanwhile, since the common electrode is connected with the bottom electrode of the storage capacitance through a via hole in the insulation layer, a high aperture ratio can be obtained and the transmittance can be increased.

### BRIEF DESCRIPTION OF DRAWINGS

In order to describe the technical solutions of the embodiments of the invention, it will give a brief description to the figures of the embodiments below. Obviously, the below described figures are only relate some embodiments of the invention, and not intended to restrict the invention.

FIG. 1 is a schematic view showing a conventional array substrate in an ADS mode;

FIG. 2 is a schematic view showing an array substrate according to a first embodiment of the invention;

FIG. 3a and FIG. 3b are schematic views showing a method of manufacturing the array substrate according to the first embodiment of the invention; and

FIG. 4 is a schematic view showing an array substrate according to a second embodiment of the invention.

### DETAILED DESCRIPTION

In order to make aims, technical solution and advantages of the embodiments of the invention to be clearer, the technical solutions of the embodiments of the invention will be described below clearly and fully in connection with the figures of the embodiments of the invention. Obviously, the described embodiments are a portion of the embodiments of the invention, not to be all embodiments. Based on the described embodiments of the invention, all additional embodiments, which could be obtained by those skilled in the art without paying creative work, belong to the scope of the protection of the invention.

### First Embodiment

The present embodiment provides an array substrate, which may employ the ADS mode. As shown in FIG. 2, the array substrate comprises a gate line and a data line which define a pixel region, and the pixel region comprises a thin film transistor region and an electrode pattern region. A gate electrode 2, a gate insulation layer 3, an active layer 4, a source electrode 5, a drain electrode 6, and a passivation layer 9 are formed in the thin film transistor region. The gate insulation layer 3, a pixel electrode 7, the passivation layer 9 and a common electrode 8 are formed in the electrode pattern region. The common electrode 8 and the pixel electrode 7 may form a multi-dimensional electric field. Alternatively, a protection layer 12 may be formed on the gate insulation layer 3, the source electrode 5 and the drain electrode 6, and subsequently, a black matrix layer 10 may be formed above the source electrode 5, the drain electrode 6 and a TFT channel. Alternatively, the black matrix layer 10 may be directly formed above the source electrode 5, the drain electrode 6 and the TFT channel without forming the protection layer 12.

When the protection layer 12 is formed, the black matrix layer 10 is formed on a portion of the protection layer 12 corresponding to the thin film transistor, and a color resin layer 11 is formed between the surface, which is formed by the protection layer 12 and the black matrix layer 10, and the pixel electrode 7. When the black matrix layer 10 is directly formed on the thin film transistor without forming the protection layer 12, the color resin layer 11 is formed between the surface, which is formed by the gate insulation layer 3 and the black matrix layer 10, and the pixel electrode 7. The protection layer 12 is advantageous to make the pixel region to be more flat.

A storage capacitance bottom electrode 13 formed by the metal material for the gate electrode 2 is further provided in the electrode pattern region. An insulation layer via hole is formed above the storage capacitance bottom electrode 13. The insulation layer via hole penetrates the passivation layer 9, the color resin layer 11, the protection layer 12 (if is formed) and the gate insulation layer 3. The common electrode 8 is connected with the storage capacitance bottom electrode 13 by the insulation layer via hole.

In the present embodiment, the storage capacitance bottom electrode 13 may be a common electrode line (Cst on common) to provide a constant voltage to the common electrode 8, or may be a portion of the gate line (Cst on Gate).

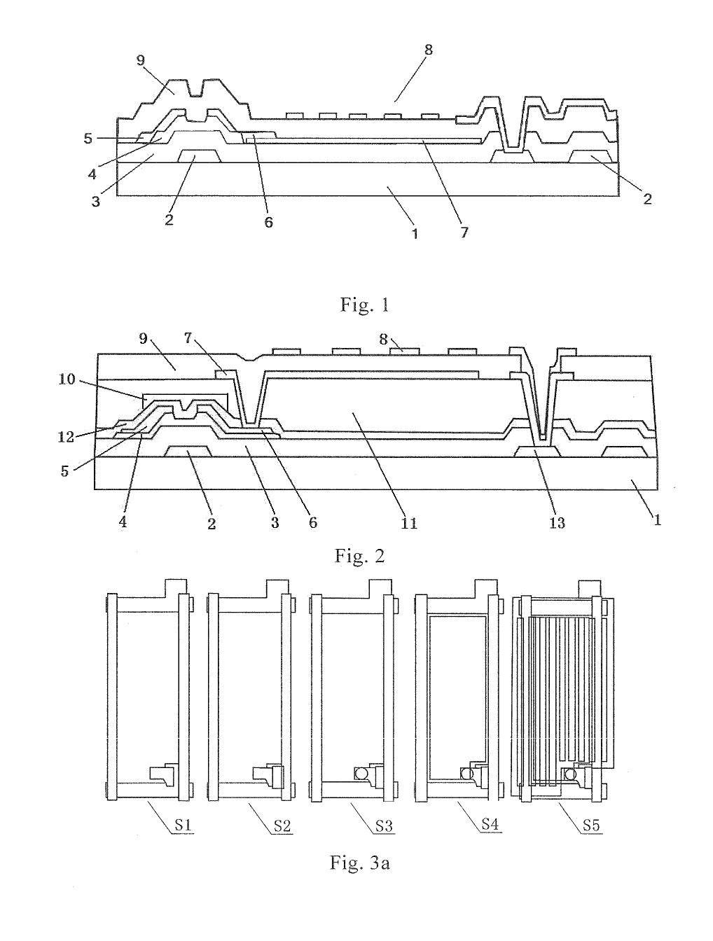

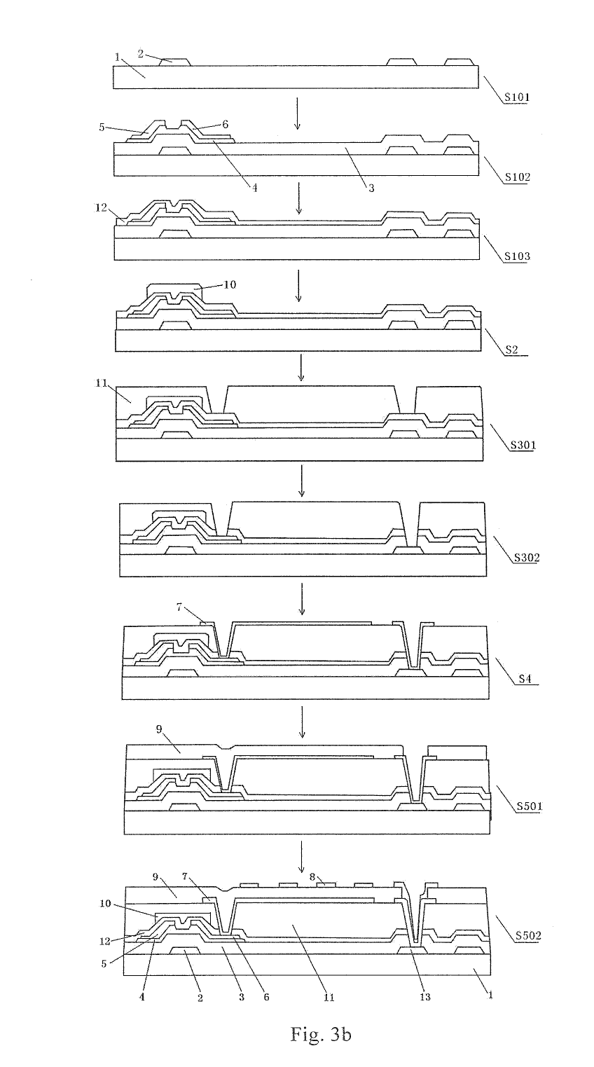

In addition, the present embodiment further provides a method of manufacturing the array substrate. As shown in FIGS. 3a and 3b, the method may comprise: firstly forming the gate line, the gate electrode 2, the gate insulation layer 3, the active layer 4, the source electrode 5, the drain electrode 6 and the data line, so as to form the thin film transistor region; subsequently forming the color resin layer 11; and finally forming the pixel electrode 7, the passivation layer 9 and the common electrode 8, so as to form the electrode pattern region. For example, the method comprises the following steps:

Step S1: firstly forming the gate line, the gate electrode 2, the gate insulation layer 3, the active layer 4, the source electrode 5, the drain electrode 6 and the data line so as to form the thin film transistor region, and subsequently forming the protection layer 12 by an insulation material. The step may comprise the following steps S101, S102 and S103.

Step S101: depositing a first metal layer having conductivity on a substrate 1, and forming the gate line, the gate electrode 2, and the storage capacitance bottom electrode 13 in the electrode pattern region by using a first patterning process;

Step S102: sequentially depositing the gate insulation layer 3 formed by materials such as SiNx, SiON and the like, and a semiconductor active layer 4 formed by materials such as a-Si and the like on the substrate after step S101; depositing a second metal layer having conductivity, and forming the active layer 4, the source electrode 5, the drain electrode 6 and the data line through a second patterning process by using a halftone mask or a gray tone mask so as to form the thin film transistor region;

Step S103: forming the protection layer 12 by using materials such as SiNx and the like on the substrate after step S102 to protect the pixel region.

Step S2: depositing an opaque resin layer on the substrate after the step S1, and forming the black matrix layer 10 at the predetermined position in the thin film transistor region by using a third patterning process.

Step S3: forming the color resin layer 11. The step comprises the following steps S301 and S302:

Step S301: depositing a red resin layer R on the substrate after the step S2 and performing a fourth patterning process, depositing a green resin layer G and a blue resin layer B and performing a fifth patterning process and a sixth patterning process in a manner similar to the red resin layer R, so as to form the color resin layer 11, and etching away the color resin layer 11 above the storage capacitance bottom electrode 13;

Step S302: etching away the gate insulation layer 3 and the protection layer 12 above the storage capacitance bottom electrode 13 by using a seventh patterning process, to expose the storage capacitance bottom electrode 13 and form the insulation layer via hole opened upwardly.

In the following steps S4 and S5, the pixel electrode 7, the passivation layer 9 and the common electrode 8 will be formed. For example, these steps are performed as follows

Step S4: depositing a first transparent conductive layer on the substrate after the step S3, and forming the pixel electrode 7 by using an eighth patterning process;

Step S5: forming the passivation layer 9 and the common electrode 8. The common electrode 8 is connected with the storage capacitance bottom electrode 13 by the insulation layer via hole formed in the above Step S302. The step comprises the following steps S501 and S502:

Step S501: depositing a transparent resin material layer on the substrate after the step S4, and forming the passivation layer 9 by using a ninth patterning process;

Step S502: depositing a second transparent conductive layer on the substrate after the step S501, and forming the common electrode 8 by using a tenth patterning process.

In the above described manufacturing method, the materials for forming the opaque resin layer preferably have a sheet resistance greater than 10¹² Ω/sq, a thickness of 0.5 μm˜2 μm, and an Optical density (OP) larger than 4.

Preferably, the materials for forming the R, G, and B resin layers have a dielectric constant in the range of 3˜5 F/m and a thickness of 1 μm˜4 μm.

The materials for forming the first and second transparent conductive layers preferably have wet etch selectively in relative to the wiring metal (for example, metal or alloy which has conductivity such as Mo, Al, Ti, Cu and so on), and for example are indium tin oxide (ITO), indium zinc oxide (IZO) and so on. These materials have a good transparency after a treatment of Transparent Conducting Oxide (TCO).

Preferably, the transparent resin material layer for forming the passivation layer 9 have a dielectric constant in a range of 3˜5 F/m and a thickness of 1 μm˜4 μm.

The above opaque resin layer for forming the black matrix layer, the R, G and B resin layers, and the transparent resin material layer for forming the passivation layer may use acrylate, polyimide, epoxy resin, phenol-aldehyde resin and so on as a matrix. The opaque resin layer and the R, G, and B resin layers are formed by adding pigment or dye of different color into the above matrix.

### The Second Embodiment

The present embodiment provides another array substrate. The repetitions of the above first embodiment will be omitted in the present embodiment, and it will give a detailed explanation below on the differences between the present embodiment and the first embodiment.

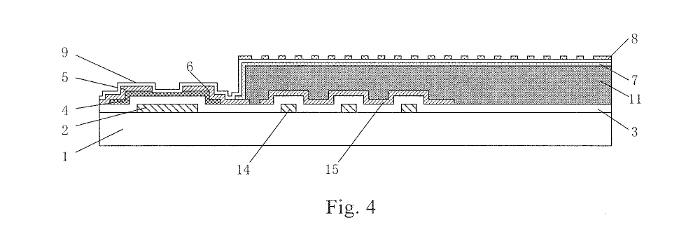

The array substrate provided by the present embodiment may employ the ADS mode. As shown in FIG. 4, the array substrate comprises a gate line and a data line which define a pixel region, and the pixel region comprises a thin film transistor region and an electrode pattern region. A gate electrode 2, a gate insulation layer 3, an active layer 4, a source electrode 5, a drain electrode 6, and a passivation layer 9 are formed in the thin film transistor region. The gate insulation layer 3, a pixel electrode 7, the passivation layer 9 and a common electrode 8 are formed in the electrode pattern region. The common electrode 8 and the pixel electrode 7 may form a multi-dimensional electric field.

A reflective region pattern 14 formed by the metal material for the gate electrode 2 is disposed at the position corresponding to the electrode pattern region on the substrate 1. The gate insulation layer 3 is formed on the reflective region pattern 14. A reflective region metal electrode layer 15 formed of the metal material for the source and drain electrodes is disposed at position corresponding to the reflective region pattern 14 on the gate insulation layer 3. Thus, a trans-reflective array substrate is formed, which may be used under the environment of strong light such as outdoors.

In addition, the present embodiment also provides a method of manufacturing the array substrate. The method comprises the following steps.

Step 1: forming the gate line, the gate electrode 2 and the storage capacitance bottom electrode (not shown) by using a first metal material, and remaining a portion of the first metal material at predetermined positions in the electrode pattern region so as to form a concave-convex pattern by using the first metal material to form the reflective region pattern 14, wherein the first metal material preferably is Al, AlNd, Mo and so on;

In the present embodiment, the storage capacitance bottom electrode may be a common electrode line (Cst on common) to provide a constant voltage to the common electrode, or may be a portion of the gate line (Cst on Gate).

Step 2: forming the gate insulation layer 3, and forming a semiconductor island by using a semiconductor material to form the active layer 4, wherein the semiconductor material preferably is a-Si, p-Si, IGZO and so on;

Step 3: forming the data line, the source electrode 5 and the drain electrode 6 by using a second metal material, and remaining a portion of the second metal material on the gate insulation layer 3 corresponding to the reflective region pattern 14 to form the reflective region metal electrode layer 15, which is used to achieve the function of a reflective layer, wherein the second metal material preferably is Al, AlNd, Mo and so on;

Steps 4˜6: depositing a red resin layer R and performing a patterning process, and depositing a green resin layer G and a blue resin layer B and performing patterning processes in a manner similar to the red resin layer, so as to form the color resin layer 11;

Step 7: forming the pixel electrode 7 connected with the drain electrode 6 by using a transparent conductive material, wherein the transparent conductive material preferably is ITO, IZO and the like;

Step 8: forming the passivation layer 9 by using an inorganic insulation material, wherein the inorganic insulation material preferably is SiNx, SiOx and the like;

Step 9: forming the common electrode 8 by using a transparent conductive material, wherein the common electrode 8 is connected with the storage capacitance bottom electrode by the via hole (not shown), and the transparent conductive material preferably is ITO, IZO and the like;

Further, the black matrix layer may be subsequently formed on the thin film transistor region on the resultant array substrate by using an opaque resin layer.

It may be understood by those skilled in the art that the pixel electrode may be of a plate shape or a slit shape, and correspondingly, the common electrode may be a slit shape or a plate shape. The stack order of the pixel electrode and the common electrode may be reversed, however, the upper electrode must be of a slit shape, and the lower electrode must be of a plate-shape.

The embodiments of the invention also provide a display device, which comprises the array substrate according to the above embodiments. The display device may be any products or components having display function, such as a liquid crystal panel, an electronic paper, an OLED panel, a liquid crystal TV, a liquid crystal display, a digital photo frame, a cellar phone, a flat panel computer and so on.

The foregoing are only preferable embodiments of the invention. It is to be noted that, those with ordinary skills in the art may make various modifications and changes without departing the technical principle of the invention, and these modifications and changes should be deemed to be within the protection scope of the invention.

1. An array substrate, comprising a gate line and a data line which define a pixel region, wherein the pixel region comprises a thin film transistor region and an electrode pattern region, a gate electrode, a gate insulation layer, an active layer, a source electrode, a drain electrode and a passivation layer are formed in the thin film transistor region, the gate insulation layer, a pixel electrode, the passivation layer and a common electrode are formed in the electrode pattern region, and the common electrode and the pixel electrode are used for forming a multi-dimensional electric field; and
wherein a color resin layer is formed between the gate insulation layer and the pixel electrode.

2. The array substrate according to claim 1, wherein
the electrode pattern region further comprises a reflective region and a transmissive region,
a reflective region pattern formed of a metal material for the gate electrode is disposed at a position corresponding to the reflective region of the electrode pattern region on the substrate, the gate insulation layer is formed on the reflective region pattern; and
a reflective region metal electrode layer formed of a metal material for the source and drain electrodes is disposed at a position corresponding to the reflective region pattern on the gate insulation layer.

3. The array substrate according to claim 1, wherein a storage capacitance bottom electrode formed of a metal material for the gate electrode is disposed in the electrode pattern region, an insulation layer via hole is formed above the storage capacitance bottom electrode, and the common electrode is connected with the storage capacitance bottom electrode by the insulation layer via hole.

4. The array substrate according to claim 1, wherein a protection layer formed of an insulation material is further formed on the source electrode, the drain electrode and the gate insulation layer, and a black matrix layer is formed at a position corresponding to the thin film transistor region on the protection layer.

5. A method of manufacturing an array substrate, comprising processes of forming a pixel region, wherein the pixel region comprises a thin film transistor region and an electrode pattern region, a gate electrode, a gate insulation layer, an active layer, a source electrode, a drain electrode and a passivation layer are formed in the thin film transistor region, the gate insulation layer, a pixel electrode, the passivation layer and a common electrode are formed in the electrode pattern region, and the common electrode and the pixel electrode are used for forming a multi-dimensional electric field;
wherein after forming the gate insulation layer and before forming the pixel electrode, a color resin layer is formed above the gate insulation layer.

6. The method of manufacturing the array substrate according to claim 5, wherein
the electrode pattern region further comprises a reflective region and a transmissive region,
in a process of forming the gate electrode, a reflective region pattern formed of a metal material for the gate electrode is disposed at a position corresponding to the reflective region of the electrode pattern region on the substrate; and
in a process of forming the source and the drain electrodes, a reflective region metal electrode layer formed of a metal material for the source and drain electrodes is disposed at a position corresponding to the reflective region pattern on the gate insulation layer.

7. The method of manufacturing the array substrate according to claim 5, wherein
in a process of forming the gate electrode, a storage capacitance bottom electrode formed of a metal material for the gate electrode is disposed in the electrode pattern region; and
an insulation layer via hole is formed above the storage capacitance bottom electrode before forming the common electrode, so that the common electrode is connected with the storage capacitance bottom electrode by the insulation layer via hole.

8. The method of manufacturing the array substrate according to claim 5, wherein a protection layer formed of an insulation material is formed after forming the source and drain electrodes, and a black matrix layer is formed at a position corresponding to the thin film transistor region on the protection layer.

9. A display device, comprising the array substrate according to claim 1.

10. The display device according to claim 9, wherein
the electrode pattern region further comprises a reflective region and a transmissive region,
a reflective region pattern formed of a metal material for the gate electrode is disposed at a position corresponding to the reflective region of the electrode pattern region on the substrate, the gate insulation layer is formed on the reflective region pattern; and
a reflective region metal electrode layer formed of a metal material for the source and drain electrodes is disposed at a position corresponding to the reflective region pattern on the gate insulation layer.

11. The display device according to claim 9, wherein a storage capacitance bottom electrode formed of a metal material for the gate electrode is disposed in the electrode pattern region, an insulation layer via hole is formed above the storage capacitance bottom electrode, and the common electrode is connected with the storage capacitance bottom electrode by the insulation layer via hole.

12. The display device according to claim 9, wherein a protection layer formed of an insulation material is further formed on the source electrode, the drain electrode and the gate insulation layer, and a black matrix layer is formed at a position corresponding to the thin film transistor region on the protection layer.
